(19) United States
(12) Patent Application Publication
(10) Pub. No.: US 2004/0061169 A1
(43) Pub. Date: Apr. 1, 2004

(54) Non-volatile memory device and method of manufacturing the same

(76) Inventors: Heon-Heoung Leam, Gyeonggi-do (KR); Yong-Woo Hyung, Gyeonggi-do (KR); Young-Sub You, Gyeonggi-do (KR); Woo-Sung Lee, Gyeonggi-do (KR)

Correspondence Address: MARGER JOHNSON & McCOLLOM, P.C., 1030 S.W. Morrison Street, Portland, OR, 97205, US

(21) Appl. No.: 10/630,571

(22) Filed: Jul. 29, 2003

(30) Foreign Application Priority Data
Sep. 30, 2002 (KR) 2002-59554

(51) Int. Cl. H01L 29/788

(52) U.S. Cl. 257/315

(57) ABSTRACT

A non-volatile memory device includes gate stack structures formed on a semiconductor substrate to be separated by a first space in a first area and by a second wider space in a second area adjacent to the first area. First gate spacers of a low dielectric constant insulating material are formed on the sidewalls of the gate stack structures. Second gate spacers made of an insulating material having good step coverage are formed on the first gate spacers to fill the first space. This dual spacer structure comprising the first gate spacer and the second gate spacer prevents the creation of void between gates. Thus, it can prevent an active region from being opened in a subsequent etching process and preclude the formation of a silicide layer on the active region. Thus, the device characteristics can be substantially improved.

This application claims priority from Korean Patent Application No. 2002-59554, filed on Sep. 30, 2002, the contents of which are incorporated herein by reference in their entirety.

### BACKGROUND OF THE INVENTION

1. Field of the Invention

The present invention relates to a semiconductor device and a method of manufacturing the same. More particularly, the present invention relates to a non-volatile memory device capable of preventing the formation of voids between a gate and an adjacent gate, and a method of manufacturing the same.

2. Description of the Related Art

As semiconductor devices have been developed to have a high degree of integration, patterns formed on the chip have become smaller in size, resulting in the space between the patterns becoming narrower. In the past, polysilicon was very useful material as a wiring material such as in a gate electrode or a bit line. However, as the patterns become gradually smaller, the resistivity in the polysilicon increases, resulting in larger RC time delays and IR voltage drops. In order to improve the short channel effect and punch through caused by a decrease in the gate length of a transistor, junction depths of source/drain regions should be shallower while parasitic resistances of source/drain regions, such as sheet resistances and contact resistances, should be reduced.

Therefore, a self-aligned silicide (“salicide”) process of forming silicides on the surface of the gate electrode and the source/drain regions is used as a new metallization process. This process reduces the resistivity in the gate electrode and the parasitic resistances in the source/drain regions. The salicide process selectively forms the silicides only on the gate electrode and the source/drain regions. The silicide is formed with material such as titanium silicide (TiSi₂) or a group VIII metal silicide, such as PtSi₂, PdSi₂, CoSi₂ or NiSi₂.

For non-volatile memory devices having a vertically gate stack structure including a tunnel dielectric layer, a floating gate, a dielectric layer and a control gate stacked successively on a silicon substrate, as the design rule decreases to about 0.1 μm less, the silicide layer such as cobalt silicide (CoSi₂) is selectively formed only on the gate electrode by the silicide process so as to reduce the resistance of the control gate serving as a word line

When the source/drain regions of the cell transistor of the non-volatile memory device are formed with lightly doped impurity regions (referred to as “LDD” region), ON-current decreases during a read operation. However, if the source/drain regions have heavily doped impurity regions, the punch through margin of the transistor lessens and a hot carrier effect occurs. Accordingly, a method has been used where insulating gate spacers are formed on the gate sidewalls of the cell transistor; then, the source/drain regions of the LDD structure are formed using the gate spacers. Typically, a silicon nitride (Si₃N₄) has been used as the insulating material constituting the gate spacer.

However, as the spaces between the gates in the memory cell becomes narrower, with a reduction in the design rule to about 0.12 μm or less, the coupling ratio lowers due to a parasitic capacitance generated between the gates. This result in an oxide spacer having a dielectric constant lower than that of silicon nitride to be used as the gate spacer.

The coupling ratio (C/R) is the ratio of voltage coupled to the floating gate by the voltage (V_{cg}) applied to the control gate during the programming operation. As the coupling ratio becomes higher, the speed and performance of the semiconductor devices become improved. The coupling ratio (C/R) is obtained by the following equation.

C/R=C_{ONO}/(C_{ONO}+Cₜᵤₙₙₑₗ+C_{spacer}) (1)

In order to raise the coupling ratio, the ratio of C_{ONO}/Cₜᵤₙₙₑₗ should be increased or the spacer capacitance (C_{spacer}) should be decreased referring to the equation (1). Since the capacitance is proportional to a dielectric constant, the spacer should be formed from a material with a low dielectric constant so as to decrease the spacer capacitance (C_{spacer}).

Examples of non-volatile memory devices including the spacer made of a material of low dielectric constant are disclosed in Korean Patent Laid-Open Publication No. 2001-4962, Korean Patent No. 301244 and U.S. Pat. No. 6,346,725.

FIGS. 1A and 1B are cross-sectional views illustrating a conventional method of manufacturing non-volatile memory devices using oxide gate spacers.

Referring to FIG. 1A, a plurality of gate stack structures 30 are formed on a semiconductor substrate 10 having a cell area and a peripheral circuit area. Each of gate stack structures 30 consists of a tunnel dielectric layer 12, a floating gate 14, a dielectric layer 16 and a control gate 18. The floating gate 14 and the control gate 18 are formed from a polysilicon layer doped with N-type impurities, and the dielectric layer 16 comprises an ONO layer, i.e., successively stacked layers of oxide/nitride/oxide.

Then, an oxide layer 20, e.g. a high temperature oxide (HTO) layer, is deposited to a thickness about 1200˜1500 Å on the gate stack structures 30 and the substrate 10 by a chemical vapor deposition (CVD) process.

Typically, the capacitance (C_{ONO}) formed by the floating gate 14 and the control gate 18 should be increased in order to raise the coupling ratio. Since the capacitance is proportional to the area, the most commonly used method is to increase the height of the floating gate 14 to enlarge the area of the dielectric layer 16. Accordingly, the aspect ratio of the gate increases because the height of the gate stack structure 30 increases and the gate space narrows as the design rule decreases. If the oxide layer 20 is deposited on the substrate 10 having this high gate aspect ratio, voids 22 are formed between the gates because of poor step coverage of the oxide layer 20. The voids 22 are particularly severe on memory cell areas having narrow gate spaces.

Referring to FIG. 1B, the oxide layer 20 is anisotropically etched to form gate spacers 20a on both sidewalls of each of the gate stack structures 30. Next, source/drain ion implantation is performed using the gate spacers 20a as ion implantation masks. Then, a silicon nitride stopping layer 24 and an oxide insulating interlayer (ILD) 26 are successively formed on the resultant structure.

After removing the insulating interlayer 26 to the surface of the stopping layer 24 through a chemical mechanical polishing (CMP) process, the insulating interlayer 26 is etched back by a dry etching process until the surface of the control gate 18 is exposed. At this time, active regions between the gates are opened due to the voids 22 on the cell area. If a cleaning process for removing particles or native oxide films is performed in areas where the active regions are opened, the opened areas become enlarged. Therefore, when a metal silicide layer 28, such as CoSi₂, is formed on the control gate 18 by a silicidation reaction after a metal layer such as cobalt (Co) is deposited, the metal silicide layer 28 is formed on the surface of the non-uniformly opened active region. This results in deterioration of the cell transistor characteristics.

### SUMMARY OF THE INVENTION

The present invention provides a non-volatile memory device capable of preventing the void generation between gates, thereby preventing a silicide from being formed on the surface of an active region during a subsequent silicidation process.

The present invention provides a method of preventing the void generation between gates manufacturing a non-volatile memory device

A non-volatile memory device comprising a semiconductor substrate and a plurality of gate stack structures separated by a first space on a first area of the substrate and by a second wider space on a second area adjacent to the first area of the substrate is provided. First gate spacers, comprising an insulating material of a relatively low dielectric constant, are formed on the sidewalls of each of the gate stack structures. Second gate spacers, comprising an insulating material having a relatively high dielectric constant and good step coverage, are formed on the first spacers so as to fill the first space.

Preferably, the first gate spacer comprises an oxide and the second gate spacer comprises a nitride.

Also, a method of manufacturing a non-volatile memory device comprising forming a plurality of gate stack structures so as to be separated by a first space on a first area of a semiconductor substrate and by a second wider space adjacent to the first area on a second area of the substrate is provided. After forming the plurality of gate stack structures, first gate spacers, comprising an insulating material of a relatively low dielectric constant, are formed on the sidewalls of each of the gate stack structures. Then, second gate spacers, comprising an insulating material having a relatively high dielectric constant and goop step coverage, are formed on the first spacers so as to fill the first space.

According to the present invention, the gate spacer is formed with a dual spacer structure including, for example, an oxide spacer having a low dielectric constant and a nitride spacer having a good step coverage, so that the dual spacer fills up narrow spaces between the gates. Thus, the generation of voids between the gates is precluded and the opening of an active region between the gates during a subsequent etching process of an insulating interlayer is prevented. As a result, the degradation of the device characteristics can be prevented.

### BRIEF DESCRIPTION OF THE DRAWINGS

The above and other objects and advantages of the present invention will become readily apparent by reference to the following detailed description when considered in conjunction with the accompanying drawings wherein:

FIGS. 1A and 1B are cross-sectional views illustrating a conventional method of manufacturing a non-volatile memory device;

FIG. 2 is a plan view of a non-volatile memory device according to a preferred embodiment of the present invention;

FIG. 3 is a cross-sectional view of a non-volatile memory device, taken along line A-A′ of FIG. 2; and

FIGS. 4A to 4F are cross-sectional views illustrating a method of manufacturing a non-volatile memory device, taken along the line A-A′ of FIG. 2.

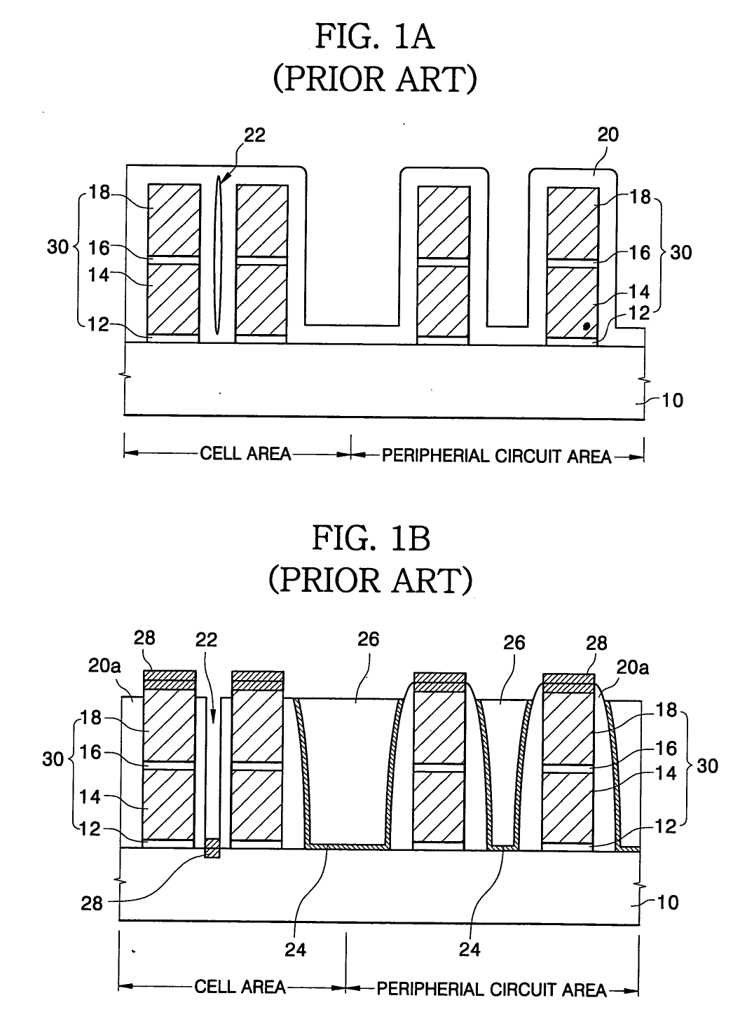

### DETAILED DESCRIPTION OF THE PREFERRED EMBODIMENTS

Hereinafter, embodiments of the present invention will be described in detail with reference to the accompanying drawings. In the following drawings, the same numerals indicate the same elements.

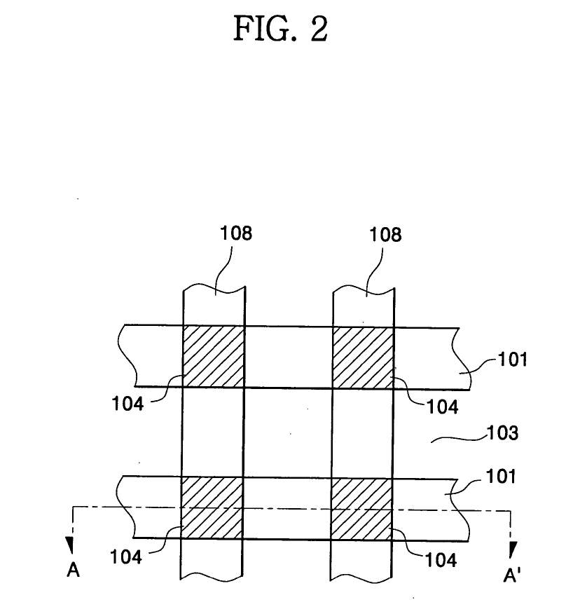

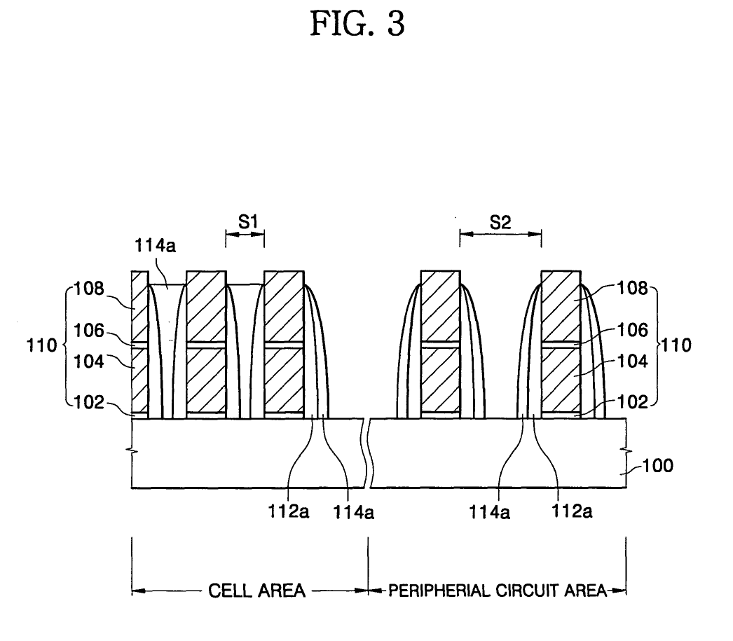

Referring to FIGS. 2 and 3, active regions 101 in which channels and source/drain regions of cell transistors that will be formed are isolated from each other by field regions 103. The active regions 101 are arranged in parallel to each other and extend in a first direction and to repeat in a second direction perpendicular to the first direction.

N number word lines are arranged to extend across the active regions 101 in the second direction and then repeated in the first direction, thereby forming a plurality of gate stack structures 110. Each of the gate stack structures 110 comprises a tunnel dielectric layer 102, a floating gate 104, an intergate dielectric layer 106 and a control gate 108, which are successively formed on a semiconductor substrate 100.

The source/drain regions (not shown) are formed in the surface portions of the exposed active region 101 between the word lines 108 which are spaced apart by a predetermined distance.

The gate stack structures 110 are separated by a first space (S1) on a first area, e.g. a memory cell area, and disposed by a second space (S2) wider than the first space (s1) on a second area adjacent to the first area, e.g., a peripheral circuit area.

Gate spacers, comprising first spacers 112a and second spacers 114a, are formed on the sidewalls of each of the gate stack structures 110. The first spacers 112a comprise an insulating material of a relatively low dielectric constant, preferably a CVD-oxide such as high temperature oxide (HTO). The second spacers 114a comprise an insulating material having a relatively high dielectric constant and good step coverage, preferably a nitride such as (Si₃N₄).

The first gate spacers 112a are formed to have a thickness sufficient to form a gap within the first space (s1), preferably, about 500 Å.

The second spacers 114a are formed so as to fill up the narrow first space (s1) between the gates and still have a thickness thinner than the first gate spacer 112a.

According to an embodiment of the present invention, the reduction of the coupling ratio caused by a parasitic capacitance between gates can be prevented by utilizing the first spacer 112a that is in direct contact with the gate comprising an oxide having a relatively low dielectric constant, and the second spacer, 114a which is formed on the first spacer, 112a comprising of a nitride having a relatively high dielectric constant and good step coverage so as to fill up the narrow first space (S1) between the gates and eliminate voids. This embodiment prevents a silicide layer from being formed on the active region between the gates during a silicidation process, because no voids are generated between the gates when depositing the gate spacers.

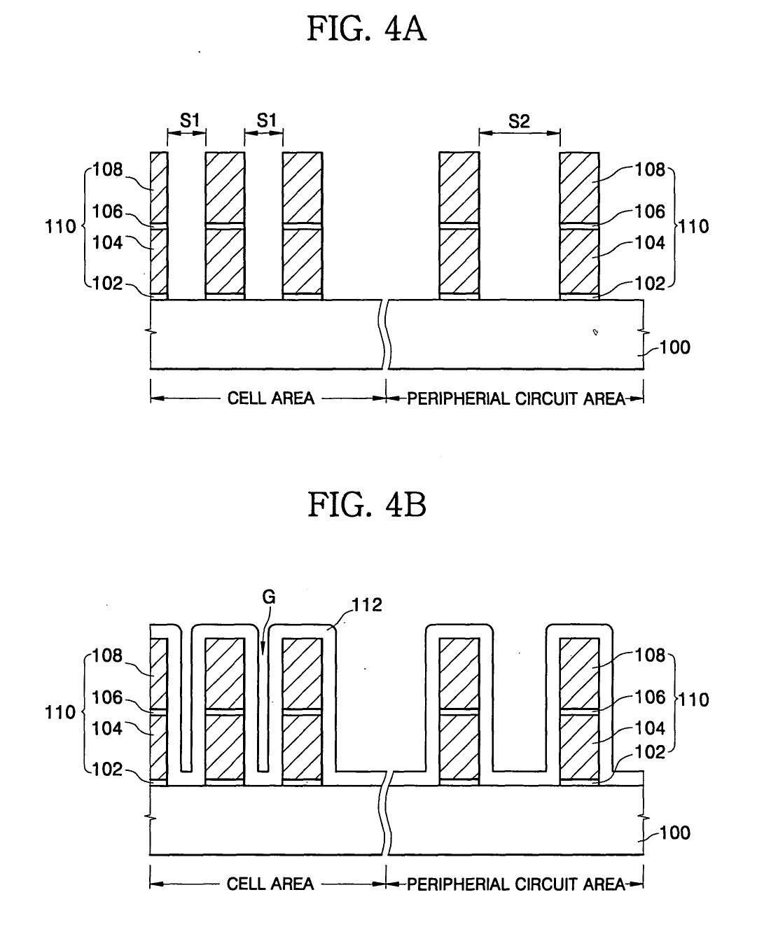

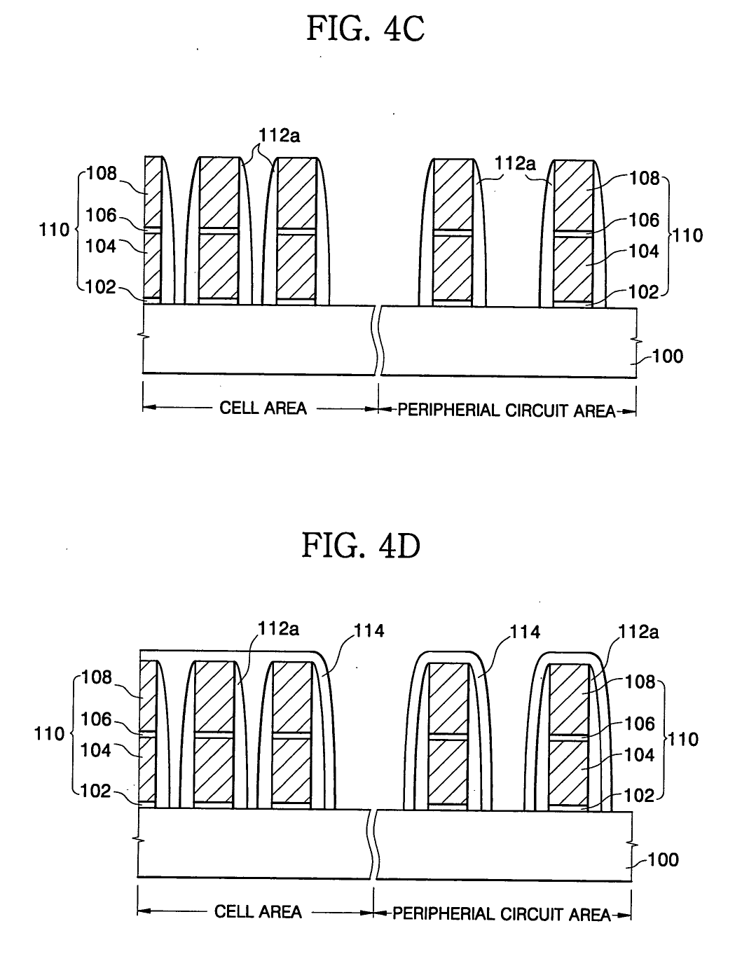

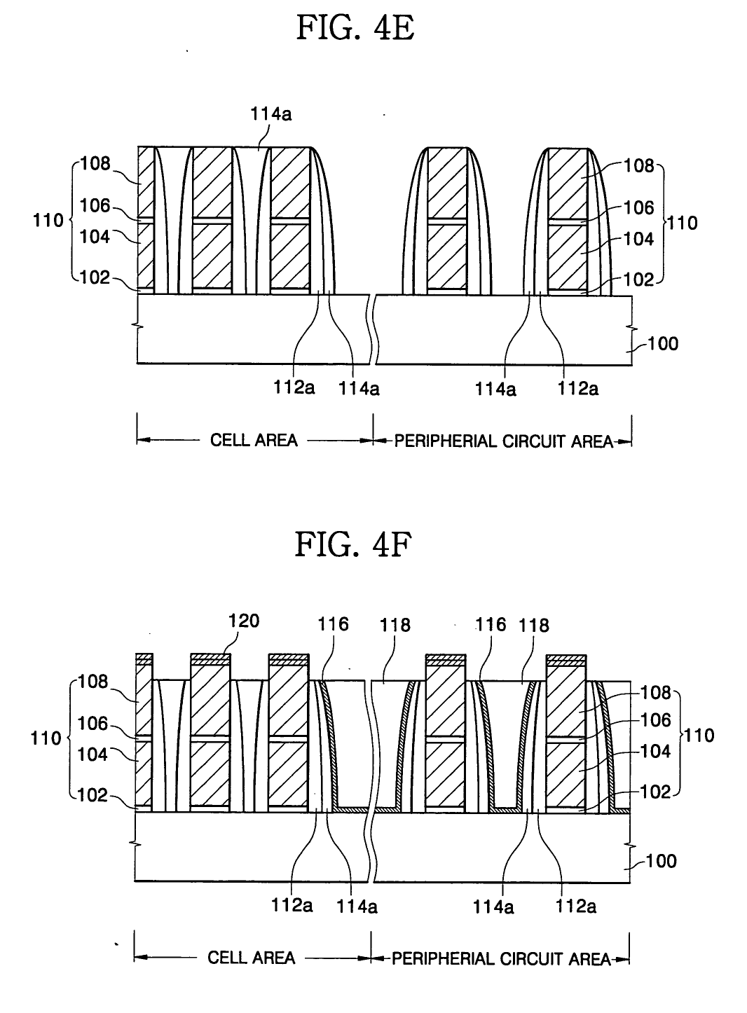

Referring to FIG. 4A, a semiconductor substrate 100 is divided into an active region (refer to 101 in FIG. 2) and a field region (not illustrated) by an isolation process such as shallow trench isolation (STI) process. Alternatively, the field region may be formed by a local oxidation of silicon (LOCOS) process, or may be formed by a self-aligned shallow trench isolation (SA-STI) process in which a floating gate and the active region are formed at the same time.

Next, a tunnel dielectric layer 102 is formed on the substrate 100 by, for example, a thermal oxidation process. The tunnel dielectric layer 102 may comprise silicon oxide or silicon oxynitride.

A floating gate layer 104 comprising polysilicon or amorphous silicon is deposited on the resultant structure including the tunnel dielectric layer 102 and then, doped with high concentration N-type impurities by a typical doping method such as POCl₃ diffusion, ion implantation or in-situ doping. The floating gate layer 104 of the non-volatile memory cell serves as a tunneling source during data programming and erasing. Thus, it is preferred that the floating gate be formed from an in-situ doped polysilicon, which is deposited using silane (SiH₄) and phosphine (PH₃) gases, because of excellent impurity doping uniformity and easy control of electrode resistance.

Considering the reliability of the tunnel dielectric layer 102, the lower portion of the in-situ doped polysilicon layer in contact with the tunnel dielectric layer 102 is deposited as a polycrystalline phase structure having excellent stress resistance characteristics, because no phase transformation occurs therein. The upper portion of the in-situ doped polysilicon layer which makes contact with a subsequent dielectric layer, is deposited as an amorphous phase structure. Preferably, the thickness of the lower portion is about 20˜50% of the thickness of the upper portion.

Next, a portion of the floating gate layer 104 on the field regions is removed using a photolithography and etching process to isolate the floating gates of the neighboring memory cells from each other.

On the resultant structure, an ONO dielectric layer 106 including a SiO₂ film with good leakage current characteristics and a low dielectric constant of about 3.9 and Si₃N₄ film having a higher dielectric constant of about 7.0, is formed through a thermal oxidation or a CVD process.

A control gate layer 108 comprising polysilicon or amorphous silicon is formed on the intergrate dielectric layer 106. The control gate layer 108 of the non-volatile memory cell is the layer to which a voltage is applied so as to transfer electrons from the substrate 100 to the floating gate layer 104 or electrons from the floating gate layer 104 to the substrate 100 during data programming and erasing. Thus, in order to prevent the deterioration of the underlying integrate dielectric layer 106 during the deposition of the control gate layer 108, a polycrystalline silicon layer of is deposited and doped by either POCl₃ diffusion or ion implantation to form the control gate layer 108. Alternatively, an in-situ doped silicon layer of amorphous phase is deposited and phase-transformed into polycrystalline phase by annealing. The annealing can be carried out as either a furnace annealing or a rapid thermal annealing (RTA). The furnace annealing may be performed for 30 minutes at a temperature of about 600˜950° C., while the RTA may be performed at a temperature of about 800˜1100° C.

Then, the control gate layer 108 the intergrate dielectric layer 106 and the floating gate layer 104 are successively dry-etched (patterned) through a photolithography and etching process, thereby forming gate stack structures 110. The gate stack structures 110 are separated by a first space (S1) on a first area, e.g. a memory cell area and by a second space (S2) wider than the first space (S1) on a second area adjacent to the first area, e.g., a peripheral circuit area.

Referring to FIG. 4B, after completing the gate patterning as describe above, a process of forming gate spacers is performed to make a transistor of an LDD structure.

Specifically, an insulating layer 112 of low dielectric constant, e.g. an oxide layer, is deposited on the gate stack structures 110 and the substrate 100 to a thickness sufficient to form a gap within the narrow first space (s1) between the gates, preferably about 500 Å.

Referring to FIG. 4C, the oxide layer 112 is anisotropically etched to form first gate spacers 112a on the sidewalls of gate stack structures 110.

The oxide layer 112 may be formed at a low pressure of about 0.4 Torr or less to improve the step coverage. However, since the low-pressure deposition reduces the deposition speed, the first gate spacers 112a may be formed by the following steps to increase of process throughput:

First, an oxide layer is deposited at a normal pressure on the substrate 100 and gate stack structures 110. Then, the oxide layer is anisotropically etched to form oxide spacers on the sidewalls of the gate stack structures 110. Next, a second oxide layer is deposited at a low pressure of about 0.4 torr or less on the oxide spacers, the substrate 100 and the gate stack structures 110, and then isotropically etched. This two deposition/etching processes enhance the step coverage of the oxide layer when forming the first gate spacers 112a.

Referring to FIG. 4D, an insulating layer having good step coverage, e.g. a nitride layer 114 such as Si₃N₄, is deposited on the first gate spacers 112a, the gate stack structures 110 and the substrate 100 to a thickness that is thinner than that of the oxide layer 112, preferably about 400 Å.

Referring to FIG. 4E, the nitride layer 114 is anisotropically etched to form second gate spacers 114a on the first gate spacers 112a. Here, the second gate spacer 114a fills up the gap formed within the first space (S1) due to the first gate spacers 112a. Accordingly, no voids have formed within the narrow first space (S1) between the gate structures 110 due to the dual spacer structure including the first gate spacer 112a and the second gate spacer 114a, and thus no active regions have opened between the gates from the etching process of the insulating interlayer. Accordingly, no silicide layer is formed on the active region in a subsequent silicidation process, thereby preventing the transistor characteristics from being degraded.

Referring to FIG. 4F, source/drain ion implantation is carried out using the first and second gate spacers 112 and 114a as an ion implantation mask. Then, a stopping layer 116, formed of a material such as silicon nitride, and an insulating interlayer 118, formed of an insulating material such as oxide, are successively formed on the resulting structure.

The insulating interlayer 118 is removed to the surface of the stopping layer 116 through a chemical mechanical polishing (CMP) process, and then etched back by a dry etching process until the surface of the gate stack structure 110 is exposed.

In order to remove contaminants, including particles on the substrate 100 and a native oxide film formed on the surface of a silicon region, a typical wet cleaning process using a solution of hydrofluoric acid (HF) and standard cleaning-1 (SC-1) of organic material, where NH₄OH, H₂O₂ and H₂O are mixed with a ratio of 1:4:20 is carried out. Then, the substrate 100 is moved to an RF sputter reaction chamber. After performing RF plasma etching to remove a native oxide film generated during the movement of the substrate, a metal layer, e.g. a cobalt layer, is in-situ deposited by sputtering on the surface of the substrate 100.

A first heat treatment causes a silicidation reaction where the metal layer makes contact with the silicon, thereby forming a first phase metal silicide, e.g. a cobalt monosilicide (CoSi), on the gate stack structures 10, i.e. the control gates 108.

After removing the unreacted metal layer by wet etching, a second heat treatment is performed to phase-transform first phase the metal silicide into a second phase metal silicide 120, e.g. a cobalt disilicide (CoSi₂) of low resistivity.

According to an embodiment of the present invention as described above, gate spacers are formed with a dual spacer structure including an oxide spacer having a low dielectric constant and a nitride spacer having good step coverage, to fill up narrow spaces between the gate structures. This prevents the generation of voids between the gates and the opening of active regions between the gate structures can be prevented. Thus, no silicide layer is formed on an active region and there is no resulting deterioration of the transistor characteristics.

Although embodiments of the present invention have been described, it is understood that the present invention should not be limited to these embodiments. Various changes and modifications can be made by one skilled in the art within the spirit and scope of the present invention as hereinafter claimed.

What is claimed is:

1. A non-volatile memory device comprising:
a semiconductor substrate;
gate stack structures separated by a first space on a first area of the substrate and by a second space, wider than the first space, on a second area of the substrate adjacent to the first area;
first gate spacers formed on sidewalls of the gate stack structures, the first gate spacers comprising an insulating material having a relatively low dielectric constant; and
second gate spacers formed on the first spacers to fill the first space, the second gate spacers comprising an insulating material having a relatively high dielectric constant.

2. The device as claimed in claim 1, wherein the first gate spacers comprise an oxide and the second gate spacers comprise a nitride.

3. The device as claimed in claim 1, wherein the first gate spacers are formed to have a thickness sufficient to form a gap within the first space.

4. The device as claimed in claim 3, wherein a thickness of the first gate spacers is about 500 Å.

5. The device as claimed in claim 1, wherein the second gate spacers are thinner than the first gate spacers.

6. The device as claimed in claim 1, wherein each of the gate stack structures is formed by sequentially stacking a tunnel dielectric layer, a floating gate, an intergate dielectric layer and a control gate.

7. The device as claimed in claim 6, wherein the control gate comprises a polysilicon layer and a metal silicide layer formed on the polysilicon layer.

8. The device as claimed in claim 7, wherein the metal silicide layer comprises one selected from the group consisting of cobalt silicide (CoSi₂), titanium silicide (TiSi₂) and nickel silicide (NiSi₂).

9. A method of manufacturing a non-volatile memory device, the method comprising:
forming gate stack structures on a semiconductor substrate, the gate stack structures separated by a first space on a first area of the substrate and by a second space, wider than the first space, on a second area of the substrate adjacent to the first area;
forming first gate spacers on sidewalls of the gate stack structures, the first gate spacers comprising an insulating material having a relatively low dielectric constant; and
forming second gate spacers on the first spacers to fill the first space, the second gate spacers comprising an insulating material having a relatively high dielectric constant.

10. The method as claimed in claim 9, wherein the first gate spacers comprise an oxide and the second gate spacers comprise a nitride.

11. The method as claimed in claim 9, wherein the first gate spacers are formed to have a thickness sufficient to form a gap within the first space.

12. The method as claimed in claim 11, wherein the first gate spacers are formed to have a thickness of about 500 Å.

13. The method as claimed in claim 9, wherein the second gate spacers are thinner than the first gate spacers.

14. The method as claimed in claim 9, wherein the first gate spacers are formed at a low pressure of about 0.4 Torr or less so as to improve the step coverage.

15. The method as claimed in claim 9, wherein forming the first gate spacers comprises:
depositing a first insulating layer for the first gate spacer on the substrate and the gate stack structures;
anisotropically etching the first insulating layer to form first insulating layer spacers on the sidewalls of the gate stack structures;
depositing a second insulating layer for the first gate spacer at a pressure of about 0.4 Torr or less on the substrate, the first insulating spacers and the gate stack structures; and
anisotropically etching the second insulating layer to form second insulating layer spacers on the first insulating layer spacers.

16. The method as claimed in claim 9, wherein the gate stack structure is formed by sequentially stacking a tunnel dielectric layer, a floating gate, an integrate dielectric layer and a control gate.

17. The method as claimed in claim 16, wherein the control gate comprises a polysilicon layer and a metal silicide layer formed on the polysilicon layer by a silicidation reaction.

18. The method as claimed in claim 17, wherein the metal silicide layer comprises one selected from the group consisting of cobalt silicide (CoSi₂), titanium silicide (TiSi₂) and nickel silicide (NiSi₂).

19. A non-volatile memory device comprising:
a semiconductor substrate;
a plurality of gate stack structures separated by a first space on a first area of the substrate and by a second space, wider than the first space, on a second area of the substrate adjacent to the first area;
first gate spacers formed on sidewalls of each of the gate stack structures, the first gate spacers comprising an insulating material having a first dielectric constant; and
second gate spacers formed on the first spacers so as to fill the first space, the second gate spacers comprising an insulating material having a second dielectric constant substantially higher than the first dielectric constant.

20. A method of manufacturing a non-volatile memory device, the method comprising:
forming a plurality of gate stack structures on a semiconductor substrate, the gate stack structures separated by a first space on a first area of the substrate and by a second space, wider than the first space, on a second area of the substrate adjacent to the first area;
forming first gate spacers on sidewalls of the gate stack structures, the first gate spacers comprising an insulating material having a first dielectric constant; and
forming second gate spacers on the first spacers to fill the first space, the second gate spacers comprising an insulating material having a second dielectric constant substantially higher than the first dielectric constant.
